(19) United States
(12) Patent Application Publication
(10) Pub. No.: US 2008/0187764 A1
(43) Pub. Date: Aug. 7, 2008

(54) NANO- OR MICRO-SCALE ORGANIC-INORGANIC COMPOSITE DEVICE AND METHOD FOR PRODUCING THE SAME

(75) Inventors: Won Cheol JUNG, Seoul (KR); Seok Gwang DOO, Seoul (KR); Sung Ho PARK, Suwon-si (KR); Sang Cheol PARK, Seoul (KR); Sang Hoon YOO, Daejeon (KR); Sung Wan KIM, Seoul (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 11/859,406

(22) Filed: Sep. 21, 2007

(30) Foreign Application Priority Data
Feb. 5, 2007 (KR) 10-2007-0011501

(51) Int. Cl. B32B 15/08; C25D 1/00

(52) U.S. Cl. 428/419; 205/78; 428/457; 428/500; 428/688; 428/704; 977/734; 977/742

(57) ABSTRACT

Disclosed herein is a nano- or micro-scale organic-inorganic composite device and a method for producing the same. The nano- or micro-scale organic-inorganic composite device includes a first electrode, a second electrode, and a photoactive layer formed of a fullerene-conducting polymer composite interposed between opposing surfaces of the first electrode and the second electrode, and a method of producing a nano- or micro-scale organic-inorganic composite device capable of mass production of the nano- or micro-scale organic-inorganic composite device, by producing an integrated structure of nano- or micro-scale organic-inorganic composite devices of a uniform size and quality using a porous template, where each device includes a first and second electrode, and a photoactive layer.

This application claims priority to Korean Patent Application No. 10-2007-0011501, filed on Feb. 5, 2007, and all the benefits accruing therefrom under 35 U.S.C. §119, the content of which is incorporated herein by reference in its entirety.

### BACKGROUND OF THE INVENTION

1. Field of the Invention

The invention relates to a nano- or micro-scale organic-inorganic composite devices and methods for their manufacture. In particular, present invention relates to a nano- or micro-scale organic-inorganic composite device that includes a first electrode, a second electrode, and a photoactive layer formed of a fullerene-conducting polymer composite interposed between the first electrode and the second electrode, and to a method of producing nano- or micro-scale organic-inorganic composite devices, using porous templates, to provide integrated nano- or micro-scale organic-inorganic composite devices with uniform size and quality, each including electrodes and a photoactive layer.

2. Description of the Related Art

Recent advancements in science and technology, in particular in the field of electronics, have been enabled by advancements in metal and semiconductor technologies. In particular, recent advancements in electronics have largely been driven by reduction in the size of electronic device features such as, for example, gate size in transistors. Further device development in electronics includes two objectives: increasing the degree of integration of electronic devices and increasing the device execution speed. At present, device technology is limited in its ability to satisfy the demands of both of these objectives. In order to overcome the limitations of current device technology and meet future requirements, materials of construction for devices, having novel shapes and smaller sizes, are required. For at least these reasons, nanoscience and nanotechnology are on the rise as new fields of research to satisfy future requirements. Nanotechnology is a technology that produces and operates objects on a nanometer scale to provide improved electronic storage or administration of information by reduced device size. Thus, nanotechnology is at the forefront as a core industrial technology of the twenty first century, including information technology and biotechnology. Nanoscience can be classified into two major fields, including materials science for providing materials such as those based on carbon nanotubes, fullerenes (C₆₀), mesoporous materials, and metal and semiconductor nanocrystals (nanocrystals, nanoclusters and quantum dots), and the field of controls and applications which utilizes methods such as STM, AFM, and lithography.

Nano-electromechanical systems (“NEMS”) and micro-electromechanical systems (“MEMS”) refer to subminiature precision machinery technology, which is expected to be a major industry that will supplant semiconductor technology. Subminiature precision machinery technology is a technology derived from semiconductor technology, and uses three dimensions to apply nanotechnology to various conventional devices. Ongoing research focuses on development of materials such as nanoparticles, nanowires, or micro-multilayer structures. Research investigating electrochemical production methods for nano-structures is at the fore because of its potential to provide economical cost reduction, convenient operation, and potential ability to provide complex shapes.

### BRIEF SUMMARY OF THE INVENTION

Therefore, the illustrated exemplary embodiments have been made in view of the above problems, to provide a nano- or micro-scale organic-inorganic composite device that includes a first electrode, a second electrode, and a photoactive layer formed of a fullerene-conducting polymer composite interposed between opposing surfaces of the first electrode and the second electrode.

In an embodiment, provided is a method capable of mass production of organic-inorganic composite devices comprising simultaneously producing an integrated structure of organic-inorganic composite devices of a uniform size and quality with a porous template, in which each organic-inorganic composite device includes electrodes and a photoactive layer.

In another embodiment, a nano- or micro-scale organic-inorganic composite device is provided that includes a first electrode, a second electrode, and a photoactive layer formed of a fullerene-conducting polymer composite interposed between opposing surfaces of the first electrode and the second electrode.

In another embodiment, a method for producing an organic-inorganic composite device comprises: preparing a porous template containing a plurality of hollow channels; forming a first electrode by electrodeposition by electroplating a metal in a lower portion of each hollow channel of the porous template; forming a photoactive layer formed of a fullerene-conducting polymer composite on a surface of each first electrode in each hollow channel of the porous template; forming a second electrodes on a surface of each photoactive layer opposite the first electrode in each hollow channel of the porous template; and removing the porous template.

### BRIEF DESCRIPTION OF THE DRAWINGS

The above and other features and advantages of the embodiments will be more clearly understood from the following detailed description taken in conjunction with the accompanying drawings, in which:

FIG. 1 is a cross-sectional schematic diagram showing an exemplary organic-inorganic composite device according to an embodiment;

FIG. 2 is a cross-sectional schematic diagram showing an exemplary organic-inorganic composite device produced according to another embodiment;

FIG. 3 is a schematic diagram exemplifying the application of an organic-inorganic composite device, produced according to an embodiment, to an optodevice;

FIG. 4 is a schematic diagram illustrating an exemplary method for producing an exemplary organic-inorganic composite device according to an embodiment;

FIG. 5 is a schematic view of an exemplary electrochemical polymerization apparatus for electropolymerization in a method for producing exemplary organic-inorganic composite devices using a porous template;

FIG. 6 is an optical micrograph of exemplary nanorod-shaped organic-inorganic composite devices produced according to an embodiment;

FIG. 7 is a field emission scanning electron micrograph (“FESEM”) and energy dispersive spectrograph (“EDS”) showing exemplary organic-inorganic composite nanorods produced according to Example 2;

FIG. 8 is an optical micrograph showing exemplary organic-inorganic nanorods, produced according to an embodiment, put on a circuit;

FIG. 9 is a curve showing current-voltage characteristics of an exemplary organic-inorganic composite device produced according to Example 1; and

FIG. 10 is a curve showing current-voltage characteristics of an exemplary device produced according to Comparative Example 1.

### DETAILED DESCRIPTION OF THE INVENTION

The invention will now be described in greater detail with reference to the accompanying drawings.

It will be understood that when an element is referred to as being “on” another element, or “between” or “interposed between” other elements, it can be directly in contact with the other element, or intervening elements may be present therebetween. In contrast, when an element is referred to as being “disposed on”, “formed on”, or “electrodeposited on” another element, the elements are understood to be in at least partial contact with each other, unless otherwise specified.

The terminology used herein is for the purpose of describing particular embodiments only and is not intended to be limiting of the invention. As used herein, the singular forms “a”, “an” and “the” are intended to include the plural forms as well, unless the context clearly indicates otherwise. The use of the terms “first”, “second”, and the like do not imply any particular order but are included to identify individual elements. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

In the drawings, like reference numerals in the drawings denote like elements and the thicknesses of layers and regions are exaggerated for clarity.

Thus, a nano- or micro-scale organic-inorganic composite device according to the illustrated exemplary embodiments includes a first electrode, a second electrode, and a photoactive layer formed of a fullerene-conducting polymer composite interposed between opposing surfaces of the first electrode and the second electrode. The nano- or micro-scale organic-inorganic composite device can be used for optodevices, optical sensors, solar batteries, energy sources for NEMS or MEMS, optical switches, chemical substance sensors, or biological substance sensors.

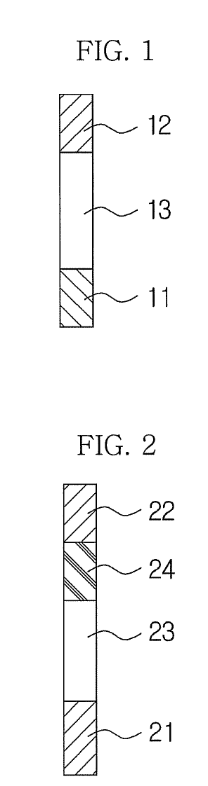

FIG. 1 is a cross-sectional schematic diagram of an organic-inorganic composite device according to an embodiment. Referring to FIG. 1, the exemplary organic-inorganic composite device includes a first electrode 11, a second electrode 12, and a photoactive layer 13 interposed between opposing surfaces of the first electrode 11 and the second electrode 12.

Materials of the first electrode 11 and the second electrode 12 can be any conductive substance. Preferably, electrochemically stable materials are used as the electrodes, and specific examples include platinum (Pt), gold (Au), aluminum (Al), nickel (Ni), molybdenum (Mo), tungsten (W), indium-tin oxide (“ITO”), carbon, carbon nanotube, or conductive polymers, or mixtures thereof. However, in order to allow light-induced migration of the electrons in the photoactive layer of the nano- or micro-scale organic-inorganic composite device, it is preferable that the first electrode 11 and the second electrode 12 be made of metallic materials having different work functions.

The photoactive layer 13 can be formed of a fullerene-conducting polymer composite, and functions by allowing electron migration between the first electrode 11 and the second electrode 12 through the photoactive layer 13 upon exposure of the photoactive layer 13 to light. Methods for forming the photoactive layer are not particularly limited. In one exemplary embodiment, the fullerene-conducting polymer composite can be formed by dissolving a monomer comprising a fullerene along with the conductive polymer in a solvent, and electrochemically polymerizing the fullerene and conducting polymer in the resulting solution by electropolymerization. The solvent used herein is desirably a compound having chlorine and benzene groups, and which can dissolve the monomers used for the synthesis of the fullerene and conductive polymer in maximum without limitation. Examples of such a solvent include ortho-1,2-dichlorobenzene (“ODCB”), 1-chlorobenzene, or mixtures thereof, but are not limited thereto. Furthermore, an electrolyte substance can be further used as a dopant to give electrical conductivity in the polymerization process. Examples of the electrolyte substance include tetrabutylammonium tetrafluoroborate, tetraethylammonium tetrafluoroborate, or the like. The electrolyte substance may be selected depending on the polarity of the solvent.

A “fullerene” as described herein refers to an allotropic form of carbon in the form of a cluster having at least sixty carbon atoms (C₆₀) to provide a basic fullerene structure, in which the carbon atoms are arranged and coupled to one another in the shape of a sphere resembling a soccer ball, and where such fullerenes have very high electron affinity. The fullerene of the exemplary embodiments have a wide range of sizes and reactivities. The fullerene can include carbon 60 fullerene (C₆₀), carbon 70 fullerene (C₇₀), carbon 76 fullerene (C₇₆), carbon 78 fullerene (C₇₈), carbon 84 fullerene (C₈₄), or mixtures thereof, but is not limited thereto.

The conductive polymer can interchange from an insulator to a semiconductor or a conductor by chemical doping, in addition to providing the desired mechanical characteristics of polymers. Examples of the conductive polymer that can be used in the electropolymerization of the exemplary embodiments include at least one selected from the group consisting of polypyrrole, polyaniline, polythiophene, polypyridine, polyazulene, polyindole, polycarbazole, polyazine, polyquinone, poly(3,4-ethylenedioxythiophene), polyacetylene, polyphenylene sulfide, polyphenylene vinylene, polyphenylene, polyisothianaphthene, poly(2-methoxy-5-(2′ethyl)hexyloxy-p-phenylene vinylene (“MEH-PPV”), a polyethylenedioxythiophene (“PEDOT”)/polystyrenesulfonate (“PSS”) mixture, polyfuran, polythienylene vinylene, and derivatives thereof, having a functional group such as an alkane chain, a carboxylic group or an isocyanide group.

FIG. 2 is a cross-sectional schematic diagram showing an exemplary organic-inorganic composite device. As shown in FIG. 2, the organic-inorganic composite device can further include a control layer 24 formed between the photoactive layer 23 and the second electrode 22. The first electrode 21 and the second electrode 22 must have a different work function so that holes and electrons separated in the photoactive layer 23 by exposure to light can each migrate toward opposite electrodes based on their charge. Therefore, when the first electrode 21 and the second electrode 22 are made of metallic materials having the same work function, the control layer 24 can be formed between the photoactive layer 23 and the second electrode 22 so as to allow electron migration by controlling the work function at the second electrode 22 relative to that of the opposite electrode (i.e., first electrode 21). Examples of useful materials for the control layer 24 include silver (Ag), copper (Cu), cadmium (Cd), or mixtures thereof, but are not limited thereto.

An exemplary organic-inorganic composite device can include various shapes depending on the shape of the porous template used during production. In an embodiment, the organic-inorganic composite device has a nano-structure. The nano-structure herein has a shape selected from the group consisting of nanowire, nanorod, nanoneedle, nanobelt, and nanoribbon, but is not limited thereto.

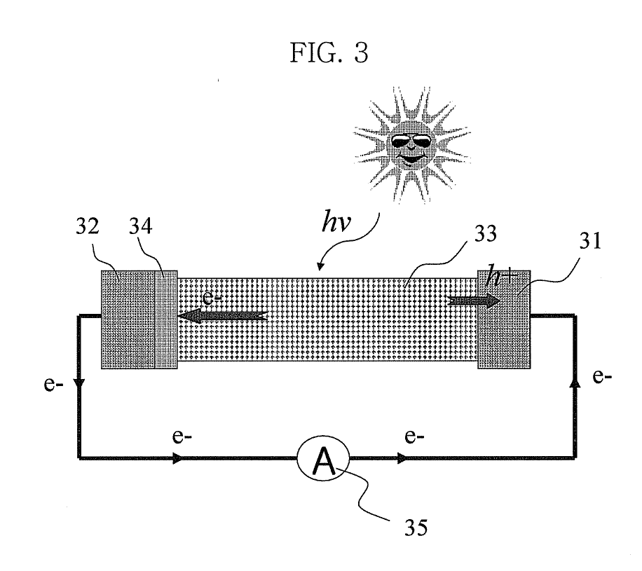

The operational principles of an exemplary nano- or micro-scale organic-inorganic composite device will next be described. FIG. 3 is a schematic diagram exemplifying the application of an organic-inorganic composite device produced according to an embodiment to an optodevice. Referring to FIG. 3, the photoactive layer 33 is formed of an organic-inorganic composite, i.e., a fullerene-conducting polymer composite.

When the optodevice in FIG. 3 absorbs light, electrons and holes separate in the photoactive layer 33. Upon exposure to light (represented as “hv” in FIG. 3), the separated electrons (e− in FIG. 3) migrate within the photoactive layer 33 toward the second electrode 32 from the direction of the first electrode 31, and the separated holes (h+ in FIG. 3) migrate toward the first electrode 31, due to the work function difference between the opposing electrodes, thereby generating an electric signal that is measurable with an ammeter 35. In an embodiment, the conductive polymer produced by the electrochemical polymerization method can be a p-type polymer. When a fullerene having high electron affinity is included with the conductive polymer to make a fullerene-conductive polymer composite, a p-n bulk-heterojunction, which shows the current-voltage characteristics close to a diode, can be formed. The nano- or micro-scale organic-inorganic composite device can be used as a solar battery when such a p-n bulk-heterojunction is used.

The exemplary organic-inorganic composite device can be nano- or micro-scale, and such a nano- or micro-scale organic-inorganic composite device can be used for optodevices, optical sensors, solar batteries, energy sources for NEMS or MEMS, optical switches, chemical substance sensors, or biological substance sensors. “Optodevices”, as used herein, refer to light-emitting devices that change electric signals to optical signals or vice versa. The optodevices include devices that absorb and transform one or more wavelengths of light interchangeably between light and electrical signals.

Another exemplary embodiment relates to a method for producing a plurality of nano- or micro-scale organic-inorganic composite devices simultaneously, including the electrodes and the photoactive layers, using a porous template having nano- or micro-scale pores.

In an embodiment, the method of formation of the photoactive layer is carried out by electropolymerization, comprising immersing the porous template in a solution containing one or more fullerenes and a conductive polymer. The fullerene-conductive polymer composite is provided by subjecting the solution to electropolymerization by passing a current through it, thereby preparing and precipitating the fullerene-conducting polymer composite electrochemically on a surface of the first electrode in each hollow channel of the porous template.

Specifically, the method includes: preparing a porous template containing a plurality of hollow channels; forming a first electrode via electrodeposition by electroplating a metal in the lower portion of each hollow channel of the porous template; forming a photoactive layer formed of a fullerene-conducting polymer composite on a surface of the first electrode in each hollow channel of the porous template; forming a second electrode on a surface of the photoactive layer opposite the first electrode in each hollow channel of the porous template; and removing the porous template.

Each step of the exemplary embodiments will be described in greater detail with reference to the accompanying drawings.

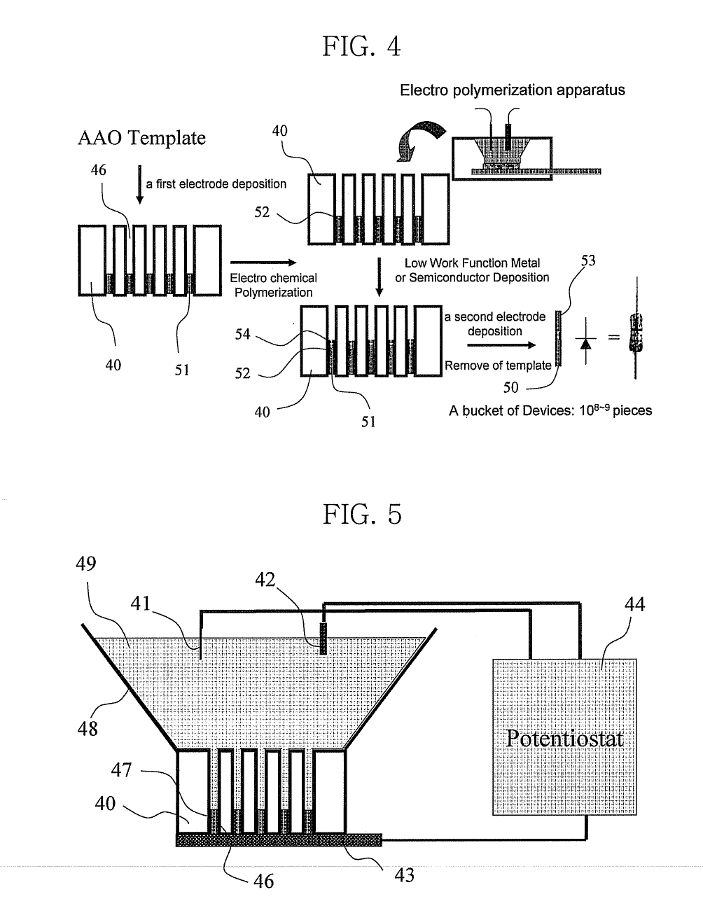

FIG. 4 is a schematic diagram showing the procedure of a method for producing an organic-inorganic composite device 45 according to an embodiment.

(a) Preparation of Porous Template

The porous template 40 that can be used in the embodiments includes a plurality of nano- or micro-scale pores 46 having a diameter of 20 to 200 nanometers. The porous template 40 is not particularly limited in its material of construction. Examples of the porous template 40 can include an anodic aluminum oxide membrane, a polycarbonate porous template, an anodic titania membrane, and a polymeric porous membrane prepared from a polymer such as polypropylene, nylon, polyester, or a block copolymer. The porous template 40 can be nano- or micro-scale, and the morphology, size, shape, and the like of the pores are not limited.

A porous template 40 comprising an anodic aluminum oxide membrane can be prepared by the anodic oxidation method. The pores (also referred to herein as “hollow channels”) in the porous template 40 are uniformly arranged. The size and depth of the pores may be controlled according to the conditions of the porous template production. In the case of the anodic aluminum oxide membrane produced by the anodic oxidation, the size and depth of the pores can be controlled by control of the oxidation conditions of the anodic oxidation, in particular by control of the solvent type, the oxidation temperature, the potential difference between the opposite electrodes, or the oxidation time, for example.

(b) Formation of First Electrode

The first electrode 51 can be formed via electrodeposition by electroplating a metal in each hollow channel of the porous template 40. The method for forming the first electrode is, however, not particularly limited. Hereinbelow, the method of electrochemical deposition of the first electrode 51 will mainly be described.

FIG. 5 is a schematic view showing an electrochemical polymerization apparatus that is used for both the electrodeposition of the metal for the first electrode 51 and second electrode 53, as well as electropolymerization to form the photoactive layer 52 for producing an organic-inorganic composite device using a porous template 40. Referring to FIG. 5, in an embodiment, a working electrode 43 can initially be formed by thermally evaporating a metal thin film on one face of the porous template 40 before forming the first electrode 51. The lower portion of the electrochemical cell 48 is then brought into electrical contact with the porous template 40 as shown in the electrochemical polymerization apparatus depicted in FIG. 5. Then, a solution 49 containing, in this step, a precursor for the substance to be electrodeposited (e.g., where solution 49 contains a metallic precursor to first electrode 51) is added to the electrochemical cell 48 via the upper portion of the electrochemical cell 48. Before electrodepositing the first electrode 51, a metal, such as Ag, can first be used to fill in the fine spaces between the porous template 40 deposited with the working electrode 43 comprising the thermally deposited metal film. Such a process can solve problems that occur where the device completely adheres to the bottom portion of the porous template 40.

The first electrode 51 is thus formed by the electrodeposition of a metal by electroplating the metal onto the area of the working electrode 43 exposed to solution 49 (where in this instance solution 49 contains a metallic precursor to first electrode 51) in each hollow channel 46 of the porous template 40, deposited with the working electrode 43.

For the material of the first electrode 51, any conductive substance may be used. In an embodiment, electrochemically stable materials are used as the first electrode 51, where specific examples include platinum (Pt), gold (Au), aluminum (Al), nickel (Ni), molybdenum (Mo), tungsten (W), indium-tin oxide (“ITO”), carbon, carbon nanotubes, conductive polymers, or the like. However, in order to cause light-induced migration of the electrons within the photoactive layer in the nano- or micro-scale organic-inorganic composite device, it is desirable that the first electrode 51 be made of a metallic material having a different work function from the second electrode 53.

A plating solution 49 is used in forming the first electrode 51. A general plating solution for a metal to be used as the electrode can be used. Although not particularly limited, in an exemplary embodiment, Orotemp 24 RTU solution (manufactured by Technic Inc.) can be used for gold plating. An exemplary voltage useful for electroplating is −1.2 V vs Ag/AgCl to −0.9 V vs Ag/AgCl.

(c) Formation of Photoactive Layer

After forming the first electrode 51 in the porous template 40, a photoactive layer 52 is formed thereon. The method for forming the photoactive layer 52 on the first electrode 51 in the porous template 40 is not particularly limited. The method of electrochemical polymerization is described below.

The porous template 40 having the first electrode 51 formed in each pore of the porous template 40 is immersed in a solution 49 which includes the fullerene and the conductive polymer dissolved therein. Then, the fullerene-conducting polymer composite is formed electrochemically and precipitated on the first electrode 51 in the pore of the porous template 40 when a current or voltage is applied, to form the photoactive layer 52 (see FIG. 4). The counter electrode 41 in the electropolymerization apparatus can be a platinum wire mesh, gold, or the like. For a reference electrode 42, Ag/AgCl, standard calomel electrode (“SCE”), can be used. Further, a potentiostat 44 portion of the electropolymerization apparatus functions to maintain constant potential.

In an embodiment, in the electrochemical polymerization process, a voltage of +1.0 V vs Ag/AgCl to +1.2 V vs Ag/AgCl, and a reaction time of 0.1 hour to 0.5 hour, are each useful.

The fullerene used in the embodiments can provide a wide reaction area. The fullerene may include carbon 60 fullerene (C₆₀), carbon 70 fullerene (C₇₀), carbon 76 fullerene (C₇₆), carbon 78 fullerene (C₇₈), or carbon 84 fullerene (C₈₄), or mixtures thereof.

The conductive polymer can characteristically transition from an insulator to a semiconductor or a conductor by chemical doping, while maintaining the mechanical characteristics of a polymer. Examples of the conductive polymer that can be used in the electropolymerization of the exemplary embodiments include at least one selected from the group consisting of polypyrrole, polyaniline, polythiophene, polypyridine, polyazulene, polyindole, polycarbazole, polyazine, polyquinone, poly(3,4-ethylenedioxythiophene), polyacetylene, polyphenylene sulfide, polyphenylene vinylene, polyphenylene, polyisothianaphthene, poly(2-methoxy-5-(2′ethyl)hexyloxy-p-phenylene vinylene (MEH-PPV), a polyethylenedioxythiophene (PEDOT)/polystyrenesulfonate (PSS) mixture, polyfuran, polythienylene vinylene, and derivatives thereof having a functional group such as an alkane chain, a carboxylic group or an isocyanide group.

Examples of the solvent for dissolving the fullerene and the conductive polymer include ortho-1,2-dichlorobenzene (“ODCB”), 1-chlorobenzene, or the like, or mixtures thereof, but not limited thereto.

The electrochemical polymerization can be performed at a selected potential in presence of an electrolyte substance as a dopant. Examples of such a dopant that may be used include tetrabutylammonium tetrafluoroborate, tetraethylammonium tetrafluoroborate, or mixtures thereof, but not limited thereto. The dopant can be selected depending on the polarity of the solvent. When the oxidation potential is too low, the initially formed polymers have a low molecular weight, and are diffused far from a solid base. Therefore, in order to form sufficiently long polymer chains that can spontaneously deposit to the solid base induced by the solvophobic effect, it is important to apply a sufficiently high potential of 1.0 V to 1.2 V vs Ag/AgCl. The solvophobic effect means that the polymer chains having a high molecular weight have low solubility, where the polymer chains above a critical molecular weight can no longer be effectively solvated.

(d) Formation of Second Electrode

After formation of the photoactive layer 52, the porous template 40 can be removed from the solution for photoactive layer formation, and a metal is electroplated on the photoactive layer 52 to form a second electrode 53 on the photoactive layer 52 in each hollow channel 46 of the porous template 40. The second electrode forming method can be the same as the first electrode forming method.

(e) Removal of Porous Template

The fabrication of an exemplary nano- or micro-scale organic-inorganic composite device is completed by dissolving the porous template 40 to remove it, and then washing the device so provided repeatedly with distilled water until the wash solution pH reaches 7.

The porous template 40 can be selectively removed by wet etching, dry etching, or pyrolysis, as appropriate to the material used to provide the porous template 40. The method for selectively removing the porous template 40 can also be carried out by photoetching or chemical etching.

Wet etching is a method carried out by using an acidic or basic etchant, such as for example an aqueous acetic acid solution, hydrofluoric acid, an aqueous phosphoric acid solution, or mixtures thereof, to selectively remove the porous template 40. Dry etching is a method carried out using gas, plasma, or ion beam. In an embodiment, reactive ion etching (RIE) can be performed by activating the reactive gas in the plasma state and chemically reacting the reactive gas with the substance to be etched to remove the material of the porous template 40 as a volatile substance. Alternatively, inductively coupled plasma reactive ion etching (“ICP-RIE”), can be used as a method for performing the dry etching process.

When using the porous template 40 to produce nano- or micro-scale organic-inorganic composite devices, the length of the first electrode 51, photoactive layer 52 and second electrode 53 can be controlled by the amount of electric charge passing through the membrane i.e., the porous template 40.

The method for producing an organic-inorganic composite device can further comprise forming a control layer 54. For the control layer 54, a metal having a low work function or a semiconductor can be used. In an exemplary embodiment, silver (Ag), copper (Cu), cadmium (Cd), or mixtures thereof, can be used, but not limited thereto. The first electrode 51 and the second electrode 53 must have a different work function so that holes and electrons that are separated by exposure of the photoactive layer 52 to light can migrate toward the opposite (first and second) electrodes. Thus, when the work functions of the first and second electrodes 51 and 53 (respectively) are the same, the control layer 54 should be formed between the photoactive layer 52 and the second electrode 53 so as to allow electron migration by controlling the work functions of the opposite electrodes.

Hereinafter, embodiments will be explained in more detail with reference to the following examples. However, these exemplary embodiments are given for the purpose of illustration and are not to be construed as limiting the scope of the invention. It will be understood by those skilled in the art that various changes can be made and equivalents can be substituted for elements thereof without departing from the scope of the invention. In addition, many modifications can be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

### EXAMPLES

### Example 1

### Production of Organic-Inorganic Composite Nanorods

Anodic aluminum oxide template (AAO template; manufactured by Whatman International, Ltd.) having a diameter of 13 mm, with channel diameter of 20 nm, was used as a porous template.

On a face of the porous template, a working electrode was formed by thermally depositing a silver thin film (200 to 300 nm thickness). The face of the porous template opposite the working electrode was then placed in contact with the bottom portion of a Teflon electrochemical cell, having an o-ring to form a seal between the AAO template and the body of the electrochemical cell, to provide an electro-polymerization apparatus. A platinum wire mesh was used for a counter electrode, and Ag/AgCl was used for a reference electrode.

Each channel of the porous template was then filled with silver plating solution (Technic ACR silver RTU solution, manufactured by Technic, Inc.) in the above-mentioned electropolymerization apparatus, and electric current applied at a charge density of 1.5 C/cm² for 30 minutes at the constant potential of −0.9 V vs Ag/AgCl, using a potentiostat, to deposit silver on the surface of the porous template covered by the electrochemical cell. Then, to form a first electrode, the porous template was filled with Au electroplating solution and Au electroplated using Orotemp 24 RTU solution (manufactured by Technic, Inc.) at −0.9 V vs Ag/AgCl.

Subsequently, a photoactive layer was formed in the porous template by electropolymerization after refilling the electropolymerization apparatus with a solution of 0.5 M of polypyrrole, a saturated concentration of fullerene (C₆₀), and 0.2 M of tetraethylammonium tetrafluoroborate in acetonitrile. During electropolymerization, the cell voltage was maintained at 1.0 V vs Ag/AgCl for 0.5 hour using the potentiostat. Subsequently, the Ag plating process was repeated at −1.0 V for about 0.5 hour to form a control layer as a capping block on the photoactive layer. The length of each portion (i.e., first electrode, photoactive layer, control layer, second electrode) of the resulting nanorod formed in each pore of the porous membrane was controlled by the amount of charge passing through the membrane as a function of time. After plating the Ag control layer, Au was electroplated using Orotemp 24 RTU solution (manufactured by Technic, Inc.) at −0.9 V vs Ag/AgCl to form second electrodes. The thermally deposited Ag backing on the first face of the porous template was dissolved by treatment with concentrated nitric acid and 3 M sodium hydroxide solution, respectively. The nanorods so produced were washed repeatedly with distilled water until the solution pH reached 7, and dried at about 25° C. in ambient atmosphere to produce nanorod-shaped organic-inorganic composite devices.

### Example 2

### Production of Organic-Inorganic Composite Nanorods

Nanorod-shaped organic-inorganic composite devices were produced in the same manner as in Example 1, except that cadmium (Cd) was plated as the control layer between the photoactive layer and the second electrodes.

### Example 3

### Production of Organic-Inorganic Composite Nanorods

Nanorod-shaped organic-inorganic composite devices were produced in the same manner as in Example 1, except that an aqueous solution containing 0.5 M aniline and 0.2 M perchloric acid was used in the polymerization process, instead of the solution of 0.5 M of polypyrrole, saturated concentration of fullerene (C₆₀), and 0.2 M tetraethylammonium tetrafluoroborate in acetonitrile in the step of forming the photoactive layer of Example 1.

### Comparative Example 1

Nanorod-shaped organic-inorganic composite devices were prepared in the same manner as in Example 1, except that fullerene (C₆₀) was excluded from the step of forming the photoactive layer of Example 1.

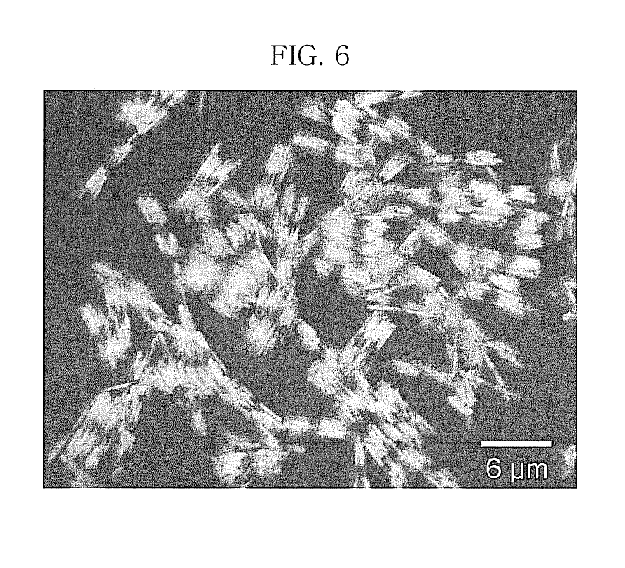

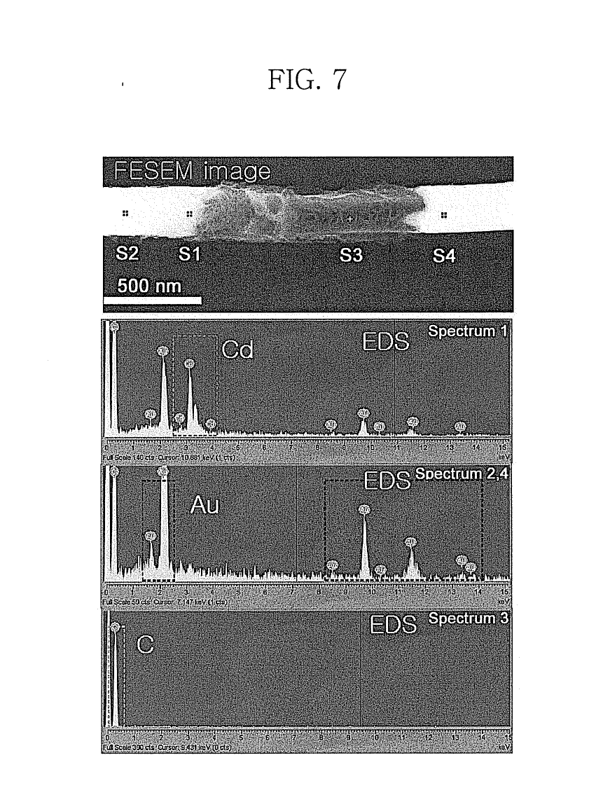

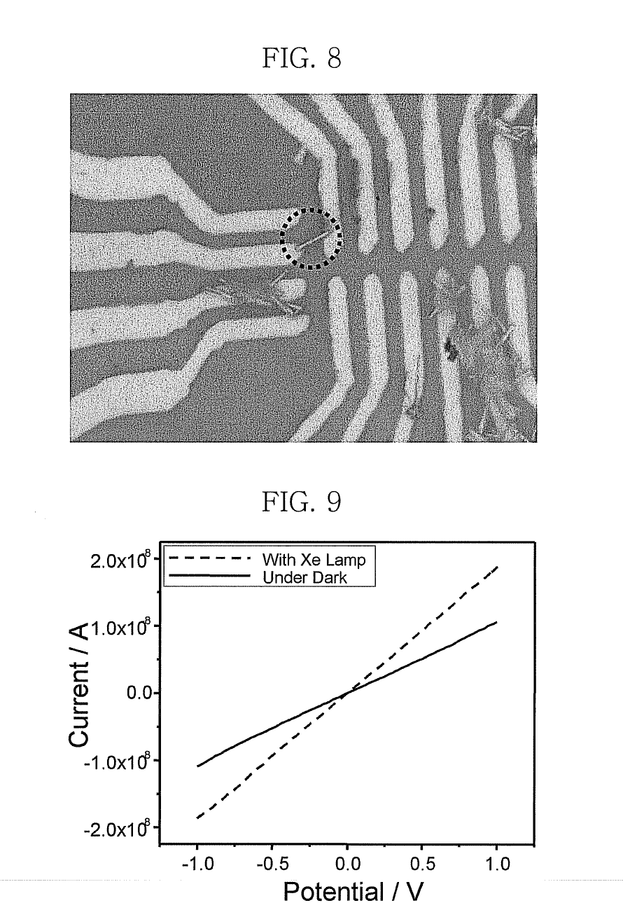

FIG. 6 is an optical micrograph of exemplary nanorods mass-produced according to Example 1, which illustrates that about 10⁸ to 10⁹ devices can be produced at once. Moreover, FIG. 7 is a field emission scanning electron micrograph (FESEM) and energy dispersive spectrograph (EDS) showing exemplary organic-inorganic nanorods produced according to Example 2. FIG. 8 is a photograph of a portion of a circuit showing exemplary nanorods placed across elements of the circuit to complete a circuit.

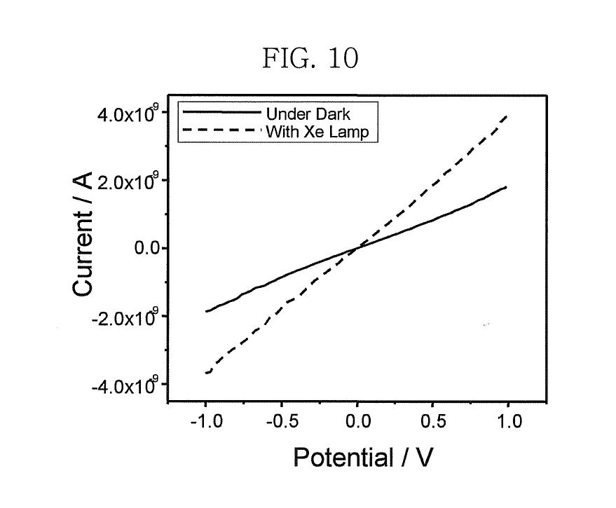

FIGS. 9 and 10 are plots of current and potential, each showing the current-voltage characteristics when Xe lamp was used (dotted line), and when no light was used (solid line), on the exemplary nanorods produced according to Example 1 and Comparative Example 1, respectively. In the case of the organic-inorganic composite devices containing fullerene-polypyrrole composite produced according to Example 1, the current increased five times at the voltage of 1.0 V as compared to the current observed for the nano devices prepared without fullerene of Comparative Example 1, thereby demonstrating that the electron migration improved when the devices included the photoactive layer formed of the fullerene-conducting polymers.

Accordingly, nano- or micro-scale organic-inorganic composite devices, of uniform size and quality, each including electrodes and a photoactive layer, were simultaneously mass-produced using the porous template. These devices can act as optical sensors or solar batteries. Thus, these devices can be used as energy sources for NEMS and MEMS, optical switches, chemical substance sensors, or biological substance sensors.

The nano- or micro-scale organic-inorganic composite devices, including the photoactive layer formed with the fullerene-conducting polymer composite, according to the embodiments, include a first electrode, a second electrode, and a photoactive layer formed of a fullerene-conducting polymer composite interposed between the first electrode and the second electrode, thereby providing a nano- or micro-scale organic-inorganic composite device with improved electron migration. Moreover, by providing the nano- or micro-scale organic-inorganic composite device producing method, wherein a porous template can be used to simultaneously produce integrated nano- or micro-scale organic-inorganic composite devices with uniform size and quality, each including the electrodes and the photoactive layer, optical sensors and solar batteries are enabled. Thus, the device can be used for energy sources for NEMS and MEMS, optical switches, chemical substance sensors, biological substance sensors, or the like.

Although the preferred exemplary embodiments have been disclosed for illustrative purposes, those skilled in the art will appreciate that various modifications, additions and substitutions are possible, without departing from the scope and spirit of the invention as disclosed in the accompanying claims.

What is claimed is:

1. A nano- or micro-scale organic-inorganic composite device comprising a first electrode, a second electrode, and a photoactive layer, the photoactive layer comprised of a conductive polymer, the conductive polymer comprised of a fullerene and a polymer, the photoactive layer interposed between the first electrode and the second electrode.

2. The device according to claim 1, wherein the first electrode and the second electrode are selected from the group consisting of platinum (Pt), gold (Au), aluminum (Al), nickel (Ni), molybdenum (Mo), tungsten (W), indium-tin oxide (ITO), carbon, carbon nanotube, and conductive polymers.

3. The device according to claim 1, wherein the organic-inorganic composite device further comprises a control layer formed between opposing surfaces of the second electrode and the photoactive layer.

4. The device according to claim 3, wherein the control layer is selected from the group consisting of silver (Ag), copper (Cu), and cadmium (Cd).

5. The device according to claim 1, wherein the fullerene is selected from the group consisting of carbon 60 fullerene (C₆₀), carbon 70 fullerene (C₇₀), carbon 76 fullerene (C₇₆), carbon 78 fullerene (C₇₈), and carbon 84 fullerene (C₈₄).

6. The device according to claim 1, wherein the conductive polymer is at least one selected from the group consisting of polypyrrole, polyaniline, polythiophene, polypyridine, polyazulene, polyindole, polycarbazole, polyazine, polyquinon, poly(3,4-ethylenedioxythiophene), polyacetylene, polyphenylene sulfide, polyphenylene vinylene, polyphenylene, polyisothianaphthene, poly(2-methoxy-5-(2′ethyl)hexyloxy-p-phenylene vinylene (MEH-PPV), a mixture of polyethylenedioxythiophene (PEDOT) and polystyrenesulfonate (PSS), polyfuran, and polythienylene vinylene, and derivatives thereof having a functional group wherein the functional group is an alkane chain, a carboxylic group or an isocyanide group.

7. The device according to claim 1, wherein the organic-inorganic composite device has a nano structure.

8. The device according to claim 7, wherein the nano structure is one selected from the group consisting of nanowire, nanorod, nanoneedle, nanobelt, and nanoribbon.

9. A method for producing the nano- or micro-scale organic-inorganic composite device comprising:
preparing a porous template containing a plurality of hollow channels;
forming a first electrode by electrodeposition by electroplating a metal in a lower portion of each hollow channel of the porous template;
forming a photoactive layer comprising a fullerene-conductive polymer composite comprising a fullerene and a conductive polymer, wherein the photoactive layer is formed on a surface of the first electrode in each hollow channel of the porous template;
forming a second electrode on a surface of the photoactive layer in each hollow channel of the porous template; and
removing the porous template.

10. The method according to claim 9, wherein the porous template is selected from the group consisting of anodic aluminum oxide membrane, polycarbonate porous template, anodic titania membrane, and a polymeric porous membrane, wherein the polymeric porous membrane comprises polypropylene, nylon, polyester, or a block copolymer.

11. The method according to claim 9, wherein the first electrode and the second electrode are selected from the group consisting of platinum (Pt), gold (Au), aluminum (Al), nickel (Ni), molybdenum (Mo), tungsten (W), indium-tin oxide (ITO), carbon, carbon nanotube, and conductive polymers.

12. The method according to claim 9, wherein formation of the photoactive layer is carried out by electropolymerization, comprising immersing the porous template in a solution containing one or more fullerenes and a conductive polymer, and subjecting the solution to electropolymerization by passing a current therethrough, and precipitating the fullerene-conducting polymer composite electrochemically on a surface of the first electrode in each hollow channel of the porous template.

13. The method according to claim 12, wherein the fullerene and the conductive polymer are dissolved in an organic solvent having chlorine and benzene groups.

14. The method according to claim 9, wherein the fullerene is selected from the group consisting of carbon 60 fullerene (C₆₀), carbon 70 fullerene (C₇₀), carbon 76 fullerene (C₇₆), carbon 78 fullerene (C₇₈), and carbon 84 fullerene (C₈₄).

15. The method according to claim 9, wherein the conductive polymer is at least one selected from the group consisting of polypyrrole, polyaniline, polythiophene, polypyridine, polyazulene, polyindole, polycarbazole, polyazine, polyquinon, poly(3,4-ethylenedioxythiophene), polyacetylene, polyphenylene sulfide, polyphenylene vinylene, polyphenylene, polyisothianaphthene, poly(2-methoxy-5-(2′ethyl)hexyloxy-p-phenylene vinylene (MEH-PPV), a mixture of polyethylenedioxythiophene (PEDOT) and polystyrenesulfonate (PSS), polyfuran, and polythienylene vinylene, and derivatives thereof having an alkane chain, a carboxylic group, or an isocyanide group.

16. The method according to claim 9, wherein the porous template is removed selectively by wet etching, dry etching, or pyrolysis.

17. The method according to claim 16, wherein the wet etching uses an acid or a base to selectively remove the porous template.

18. The method according to claim 9, wherein the method further comprises forming the control layer between the photoactive layer forming step and the second electrode forming step.

19. The method according to claim 18, wherein the control layer is selected from the group consisting of silver (Ag), copper (Cu), and cadmium (Cd).
